(19) United States
(12) Patent Application Publication
(10) Pub. No.: US 2019/0310289 A1
(43) Pub. Date: Oct. 10, 2019

(54) TEMPERATURE STABLE ROGOWSKI COIL

(71) Applicant: Eaton Intelligent Power Limited, Dublin (IE)

(72) Inventor: Theodore James Miller, Oakdale, PA (US)

(73) Assignee: Eaton Intelligent Power Limited, Dublin (IE)

(21) Appl. No.: 15/946,762

(22) Filed: Apr. 6, 2018

(51) Int. Cl. G01R 15/18

(52) U.S. Cl. CPC G01R 15/181

(57) ABSTRACT

A Rogowski coil includes a thermally stable core with a toroid body and a winding including a conductive wire. The winding is disposed in a generally helical coil (36) about the core body.

### BACKGROUND OF THE INVENTION

### Field of the Invention

The disclosed and claimed concept relates to a Rogowski coil and, more specifically, to a temperature stable Rogowski coil as well as a current sensor assembly including such a Rogowski coil.

### Background Information

A Rogowski coil is an electrical device generally used to measure alternating current (AC) or high-speed current pulses in another conductor. A Rogowski coil includes a core about which a helical coil of wire is disposed. In one common embodiment, the core is a toroid. Further, in one common embodiment, the lead from one end of the helical wire returns through the center of the coil to the other end, so that both terminals are at the same end of the coil. This configuration also improves the resistance, or immunity, to external electro-magnetic fields. The whole assembly is then wrapped around another conductor whose current is to be measured. The consistency of the winding density is critical for preserving resistance/immunity to external electro-magnetic fields and low sensitivity to the positioning of the measured conductor. That is, the voltage that is induced in the coil is proportional to the rate of change (derivative) of current in the straight conductor. Thus, the output of the Rogowski coil is usually connected to an electrical (or electronic) integrator circuit to provide an output signal that is proportional to the current. Single-chip signal processors with built-in analog to digital converters are often used for this purpose. Hereinafter, the integrator circuit/signal processor, i.e., the construct that receives the Rogowski coil output, is identified as the “output assembly.”

A Rogowski coil in this configuration is sensitive to temperature changes. That is, the core of the Rogowski coil is, typically, made from a non-metallic/non-magnetic body such as, but not limited to, a plastic. A plastic body expands and contracts with changes in temperature. Stated in more formal terms, a plastic body has a high and anisotropic coefficient of linear thermal expansion (hereinafter, and as used herein, “CLTE”). That is, as the temperature changes, a plastic body with a high CLTE changes more than a body with a low CLTE. Further, an anisotropic CLTE means that the changes in the body are not uniform in all directions. For example, a typical high temperature plastic core has a higher CLTE normal to the mold flow (e.g., about 90 ppm/degC) and a much lower CLTE parallel to mold flow (e.g., about 15 ppm/degC). Thus, a Rogowski coil core with a high CLTE stretches and shrinks as the temperature changes. This is a disadvantage and problem.

That is, the equation for the output of a Rogowski coil is:

N*μr*μ0*A/l*2*π*f*I

Where: N=number of turns, μr=relative permeability, μ0=permeability of free space, A=cross section of the core (typically measured in “squared” length units, e.g., square meters or m²), l=average circumference of the core typically measured in length units, (e.g., meters), f=the frequency of the current in the current carrying conductor measured in Hertz, and I=the applied current in the conductor. In one embodiment, a Rogowski coil has the following characteristics: N=3600, A=18×10−6 m∧2, l=0.0254 m f=60 Hz, u0=4*pi*10−7 H/m, ur=8.5. In this configuration, the resulting output of the Rogowski coil is 0.3 mV/A.

As such, when the Rogowski coil core changes with the temperature, the configuration of the wire wrapped thereabout also changes. For example, if the Rogowski coil core expands as the temperature increases, the cross section of the core increases. Further, the pitch of the wire coil, i.e., the “turns” or revolutions of the wire over a set length of the core body, changes as well. Thus, the output of the Rogowski coil changes as the temperature changes. As the output device produces an output based on a predetermined configuration of the Rogowski coil, changes in the Rogowski coil core introduce non-linearity into the output. That is, the output transfer ratio changes with temperature.

There is, therefore a need for a Rogowski coil that is less susceptible to changes in temperature. There is a further need for a Rogowski coil core that is operable with existing Rogowski coils.

### SUMMARY OF THE INVENTION

These needs, and others, are met by at least one embodiment of the disclosed and claimed concept with provides a Rogowski coil including a thermally stable core with an encircling body and a winding including a conductive wire. The winding is disposed generally in a coil about the core body.

### BRIEF DESCRIPTION OF THE DRAWINGS

A full understanding of the invention can be gained from the following description of the preferred embodiments when read in conjunction with the accompanying drawings in which:

FIG. 1 is a schematic view of a current sensor assembly with a Rogowski coil.

### DESCRIPTION OF THE PREFERRED EMBODIMENTS

It will be appreciated that the specific elements illustrated in the figures herein and described in the following specification are simply exemplary embodiments of the disclosed concept, which are provided as non-limiting examples solely for the purpose of illustration. Therefore, specific dimensions, orientations, assembly, number of components used, embodiment configurations and other physical characteristics related to the embodiments disclosed herein are not to be considered limiting on the scope of the disclosed concept.

Directional phrases used herein, such as, for example, clockwise, counterclockwise, left, right, top, bottom, upwards, downwards and derivatives thereof, relate to the orientation of the elements shown in the drawings and are not limiting upon the claims unless expressly recited therein.

As used herein, the singular form of “a,” “an,” and “the” include plural references unless the context clearly dictates otherwise.

As used herein, “structured to [verb]” means that the identified element or assembly has a structure that is shaped, sized, disposed, coupled and/or configured to perform the identified verb. For example, a member that is “structured to move” is movably coupled to another element and includes elements that cause the member to move or the member is otherwise configured to move in response to other elements or assemblies. As such, as used herein, “structured to [verb]” recites structure and not function. Further, as used herein, “structured to [verb]” means that the identified element or assembly is intended to, and is designed to, perform the identified verb. Thus, an element that is merely capable of performing the identified verb but which is not intended to, and is not designed to, perform the identified verb is not “structured to [verb].”

As used herein, “associated” means that the elements are part of the same assembly and/or operate together, or, act upon/with each other in some manner. For example, an automobile has four tires and four hubcaps. While all the elements are coupled as part of the automobile, it is understood that each hubcap is “associated” with a specific tire.

As used herein, a “coupling assembly” includes two or more couplings or coupling components. The components of a coupling or coupling assembly are generally not part of the same element or other component. As such, the components of a “coupling assembly” may not be described at the same time in the following description.

As used herein, a “coupling” or “coupling component(s)” is one or more component(s) of a coupling assembly. That is, a coupling assembly includes at least two components that are structured to be coupled together. It is understood that the components of a coupling assembly are compatible with each other. For example, in a coupling assembly, if one coupling component is a snap socket, the other coupling component is a snap plug, or, if one coupling component is a bolt, then the other coupling component is a nut.

As used herein, the statement that two or more parts or components are “coupled” shall mean that the parts are joined or operate together either directly or indirectly, i.e., through one or more intermediate parts or components, so long as a link occurs. As used herein, “directly coupled” means that two elements are directly in contact with each other. As used herein, “fixedly coupled” or “fixed” means that two components are coupled so as to move as one while maintaining a constant orientation relative to each other. Accordingly, when two elements are coupled, all portions of those elements are coupled. A description, however, of a specific portion of a first element being coupled to a second element, e.g., an axle first end being coupled to a first wheel, means that the specific portion of the first element is disposed closer to the second element than the other portions thereof. Further, an object resting on another object held in place only by gravity is not “coupled” to the lower object unless the upper object is otherwise maintained substantially in place. That is, for example, a book on a table is not coupled thereto, but a book glued to a table is coupled thereto.

As used herein, the phrase “removably coupled” or “temporarily coupled” means that one component is coupled with another component in an essentially temporary manner. That is, the two components are coupled in such a way that the joining or separation of the components is easy and would not damage the components. For example, two components secured to each other with a limited number of readily accessible fasteners, i.e., fasteners that are not difficult to access, are “removably coupled” whereas two components that are welded together or joined by difficult to access fasteners are not “removably coupled.” A “difficult to access fastener” is one that requires the removal of one or more other components prior to accessing the fastener wherein the “other component” is not an access device such as, but not limited to, a door.

As used herein, “temporarily disposed” means that a first element(s) or assembly (ies) is resting on a second element(s) or assembly(ies) in a manner that allows the first element/assembly to be moved without having to decouple or otherwise manipulate the first element. For example, a book simply resting on a table, i.e., the book is not glued or fastened to the table, is “temporarily disposed” on the table.

As used herein, “operatively coupled” means that a number of elements or assemblies, each of which is movable between a first position and a second position, or a first configuration and a second configuration, are coupled so that as the first element moves from one position/configuration to the other, the second element moves between positions/configurations as well. It is noted that a first element may be “operatively coupled” to another without the opposite being true.

As used herein, a “fastener” is a separate component structured to couple two or more elements. Thus, for example, a bolt is a “fastener” but a tongue-and-groove coupling is not a “fastener.” That is, the tongue-and-groove elements are part of the elements being coupled and are not a separate component.

As used herein, “correspond” indicates that two structural components are sized and shaped to be similar to each other and may be coupled with a minimum amount of friction. Thus, an opening which “corresponds” to a member is sized slightly larger than the member so that the member may pass through the opening with a minimum amount of friction. This definition is modified if the two components are to fit “snugly” together. In that situation, the difference between the size of the components is even smaller whereby the amount of friction increases. If the element defining the opening and/or the component inserted into the opening are made from a deformable or compressible material, the opening may even be slightly smaller than the component being inserted into the opening. With regard to surfaces, shapes, and lines, two, or more, “corresponding” surfaces, shapes, or lines have generally the same size, shape, and contours.

As used herein, a “path of travel” or “path,” when used in association with an element that moves, includes the space an element moves through when in motion. As such, any element that moves inherently has a “path of travel” or “path.” Further, a “path of travel” or “path” relates to a motion of one identifiable construct as a whole relative to another object. For example, assuming a perfectly smooth road, a rotating wheel (an identifiable construct) on an automobile generally does not move relative to the body (another object) of the automobile. That is, the wheel, as a whole, does not change its position relative to, for example, the adjacent fender. Thus, a rotating wheel does not have a “path of travel” or “path” relative to the body of the automobile. Conversely, the air inlet valve on that wheel (an identifiable construct) does have a “path of travel” or “path” relative to the body of the automobile. That is, while the wheel rotates and is in motion, the air inlet valve, as a whole, moves relative to the body of the automobile.

As used herein, the statement that two or more parts or components “engage” one another means that the elements exert a force or bias against one another either directly or through one or more intermediate elements or components. Further, as used herein with regard to moving parts, a moving part may “engage” another element during the motion from one position to another and/or may “engage” another element once in the described position. Thus, it is understood that the statements, “when element A moves to element A first position, element A engages element B,” and “when element A is in element A first position, element A engages element B” are equivalent statements and mean that element A either engages element B while moving to element A first position and/or element A engages element B while in element A first position.

As used herein, “operatively engage” means “engage and move.” That is, “operatively engage” when used in relation to a first component that is structured to move a movable or rotatable second component means that the first component applies a force sufficient to cause the second component to move. For example, a screwdriver may be placed into contact with a screw. When no force is applied to the screwdriver, the screwdriver is merely “temporarily coupled” to the screw. If an axial force is applied to the screwdriver, the screwdriver is pressed against the screw and “engages” the screw. However, when a rotational force is applied to the screwdriver, the screwdriver “operatively engages” the screw and causes the screw to rotate. Further, with electronic components, “operatively engage” means that one component controls another component by a control signal or current.

As used herein, the word “unitary” means a component that is created as a single piece or unit. That is, a component that includes pieces that are created separately and then coupled together as a unit is not a “unitary” component or body.

As used herein, the term “number” shall mean one or an integer greater than one (i.e., a plurality). That is, for example, the phrase “a number of elements” means one element or a plurality of elements. It is specifically noted that the term “a ‘number’ of [X]” includes a single [X].

As used herein, in the phrase “[x] moves between its first position and second position,” or, “[y] is structured to move [x] between its first position and second position,” “[x]” is the name of an element or assembly. Further, when [x] is an element or assembly that moves between a number of positions, the pronoun “its” means “[x],” i.e., the named element or assembly that precedes the pronoun “its.”

As used herein, “in electronic communication” is used in reference to communicating a signal via an electromagnetic wave or signal. “In electronic communication” includes both hardline and wireless forms of communication; thus, for example, a “data transfer” or “communication method” via a component “in electronic communication” with another component means that data is transferred from one computer to another computer (or from one processing assembly to another processing assembly) by physical connections such as USB, Ethernet connections or remotely such as NFC, blue tooth, etc., and should not be limited to any specific device.

As used herein, “in electric communication” means that a current passes, or can pass, between the identified elements. Being “in electric communication” is further dependent upon an element's position or configuration. For example, in a circuit breaker, a movable contact is “in electric communication” with the fixed contact when the contacts are in a closed position. The same movable contact is not “in electric communication” with the fixed contact when the contacts are in the open position.

As used herein, a “radial side/surface” for a circular or cylindrical body is a side/surface that extends about, or encircles, the center thereof or a height line passing through the center thereof. As used herein, an “axial side/surface” for a circular or cylindrical body is a side that extends in a plane extending generally perpendicular to a height line passing through the center. That is, generally, for a cylindrical soup can, the “radial side/surface” is the generally circular sidewall and the “axial side(s)/surface(s)” are the top and bottom of the soup can. Further, as used herein, “radially extending” means extending in a radial direction or along a radial line. That is, for example, a “radially extending” line extends from the center of the circle or cylinder toward the radial side/surface.

As used herein, “generally curvilinear” includes elements having multiple curved portions, combinations of curved portions and planar portions, and a plurality of planar portions or segments disposed at angles relative to each other thereby forming a curve.

As used herein, an “elongated” element inherently includes a longitudinal axis and/or longitudinal line extending in the direction of the elongation.

As used herein, “about” in a phrase such as “disposed about [an element, point or axis]” or “extend about [an element, point or axis]” or “[X] degrees about an [an element, point or axis],” means encircle, extend around, or measured around. When used in reference to a measurement or in a similar manner, “about” means “approximately,” i.e., in an approximate range relevant to the measurement as would be understood by one of ordinary skill in the art.

As used herein, “generally” means “in a general manner” relevant to the term being modified as would be understood by one of ordinary skill in the art.

As used herein, “substantially” means “for the most part” relevant to the term being modified as would be understood by one of ordinary skill in the art.

As used herein, “at” means on and/or near relevant to the term being modified as would be understood by one of ordinary skill in the art.

As used herein “CLTE” means Coefficient of Linear Thermal Expansion. Further, as used herein, a moldable material has a “normal CLTE” and a “parallel CLTE” which means the CLTE normal to the mold flow and the CLTE parallel to the mold flow, respectively. Further, as used herein, a non-moldable material has an “isotropic CLTE” which means that the CLTE is substantially the same and invariant with respect to direction.

As used herein, a “moldable material” means a plastic or similar poly material.

As used herein, a “thermally stable” element, component, or body has a CLTE (i.e., any of normal CLTE, parallel CLTE or isotropic CLTE) of less than 15 ppm/° C.

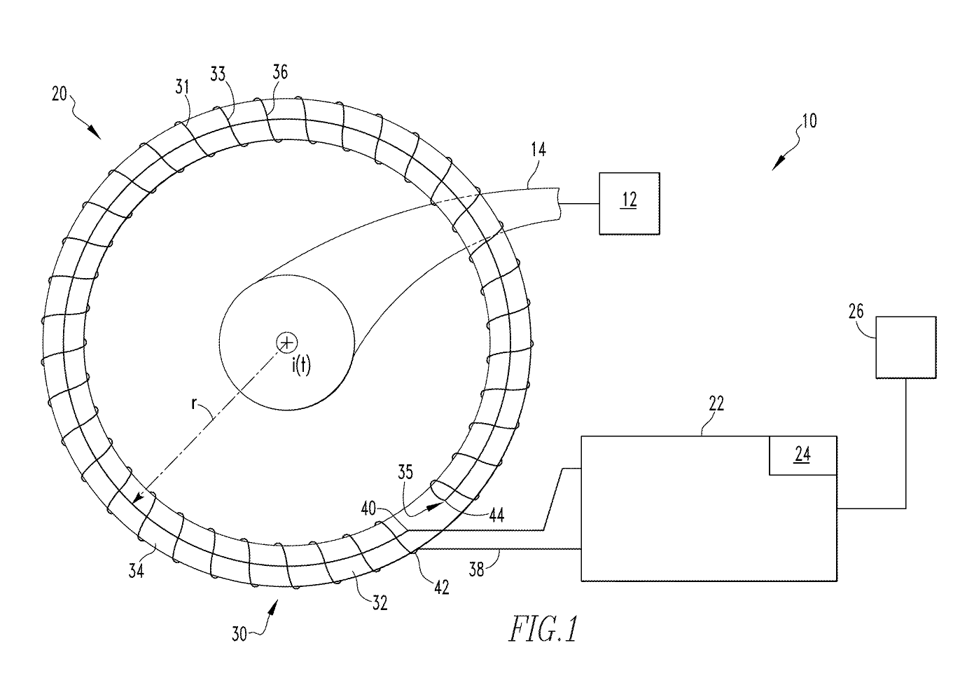

As shown in FIG. 1, an electrical apparatus 10 includes an electrical component 12 and a conductor 14. The conductor 14 transmits energy, i.e., electricity, from a source (or line), not shown, to the electrical component 12 (the load). A sensor assembly 20 is structured to measure current characteristics in the conductor 14. In an exemplary embodiment, the sensor assembly 20 includes an output assembly 22 and a Rogowski coil 30. The output assembly 22 is structured to receive an output signal from the Rogowski coil 30 and convert the signal into a representation of current characteristics. In an exemplary embodiment, the output assembly 22 includes a programmable logic circuit 24 (hereinafter “PLC 24”). As is known, the PLC 24 is structured to execute a number of commands, a program, or similar construct (hereinafter a module, not shown). The output assembly 22 also includes an output device 26 such as, but not limited to, a screen, gage, or similar construct that is structured to convey information to a human user. The PLC 24 and the output device 26 are in electric, or electronic, communication.

The Rogowski coil 30 includes a core 32 and a winding 31 of a metallic wire 33. In an exemplary embodiment, the core 32 is a thermally stable core 32. That is, the core 32 has a CLTE of less than 15 ppm/° C. As discussed below, in one embodiment, a core body 34 is a thermally stable core body 34; in other embodiments, other characteristics/elements of the core 32 make it a thermally stable core 32. As noted, the core 32 includes an encircling body 34, hereinafter “core body” 34. As used herein, an “encircling body” means a body that is structured to, and does, extend about another element. The term “encircling” is not limited to a circular or substantially circular shape. That is, for example, a square hoop is structured to “encircle” another element. In an exemplary embodiment, as shown, the core body 34 is a toroid. That is, as shown, the core body 34 has a generally circular local cross-section. As used herein, a “local cross-section” of a toroid body means the cross-section at a location on one side of, and in a plane that includes, the torus axis. Stated alternately, a “local cross-section” is a slice through one side of the toroid body with the plane of the slice including the axis of the torus. So, a generally circular local cross-section means that the shape that is rotated about an axis to create the toroid core body 34 is generally circular. In an exemplary embodiment, the inner diameter of the core body 34, i.e., the inner diameter of the torus (i.e., the inner toroid diameter), is about 1.7 inches and the outer diameter of the torus (i.e., the outer toroid diameter) is about 2.46 inches. Thus, the circular shape that defines a generally circular local cross-section has a diameter of about 0.76 inch. In another embodiment with a generally toroid core body 34, the inner diameter of the torus (i.e., the inner toroid diameter), is about 0.95 inch and the outer diameter of the torus (i.e., the outer toroid diameter) is about 1.05 inches. Thus, the circular shape that defines a generally circular local cross-section has a cross-sectional diameter of about 0.1 inch.

In another exemplary embodiment, the core body 34 is a toroid having a generally rectangular local cross-sectional shape. That is, the inner diameter of the torus is about 0.88 inch and the outer diameter of the torus 8 is about 1.05 inches. Thus, the local cross-sectional shape has a width of about 0.11 inch. Further, the local cross-sectional shape has a height of about 0.25 inch.

As is known, a winding 31 includes an elongated element that is structured to, and does, wrap about the core body 34 in a generally helical manner. In an exemplary embodiment, the winding 31 includes the metallic wire 33, such as, but not limited to, a copper wire, disposed generally helically about the core body 34 thereby forming a coil 36. In an exemplary embodiment, the wire 33 has a CLTE of about 16 ppm/degC. In one exemplary embodiment, not shown, the metallic wire 33 is a small gauge wire such as, but not limited to a 36 AWG wire. Turns of the coils 36 are butted against each other and multiple layers of windings are used. In one embodiment wherein the core body 34 is solid, the layers of the coil 36 are alternately wound clockwise and counter-clockwise so that the leads 38, 40 (discussed below) extend from the core body 34 near each other.

In another exemplary embodiment, as shown schematically, the core body 34 defines a central passage 35 that extends along a centerline of the core body 34. In this embodiment, the wire 33 has a first end or first lead 38, and, a second end or second lead 40. The first lead 38 transitions into the helical coil 36. That is, the first lead 38 extends from the core body 34 and is contiguous with a first end 42 of the coil 36 (hereinafter “coil first end” 42). The coil 36 extends over 360° of the toroid core body 34 and the coil ends at a second end 44 of the coil 36 (hereinafter “coil second end” 44). The second lead 40 begins at, and is contiguous with, the coil second end 44. The second lead 40 doubles back and extends, generally, through the center of the coil 32 and the core body 34 until radially exiting the coil 32 and the core body 34 at a location adjacent the first lead 38 and/or the coil first end 42. Stated alternately, the second lead 40 returns through the center of the coil 36 to the coil first end 42 and extends radially therefrom. Each of the first lead 38 and the second lead 40 are in electric, or electronic, communication with the output assembly 22. When exposed to an electric current passing through the core body 34 the metallic wire 34, and therefore the Rogowski coil 30, generates an output signal that is communicated to, and through, the first lead 38 and the second lead 40.

In an exemplary embodiment, the core body 34 is a thermally stable core body 34. That is, the core body 34 has a CLTE of less than about one of 15 ppm/° C., 12 ppm/° C., 10 ppm/° C., or 8 ppm/° C. Further, in one embodiment, the core body 34 has a CLTE of about 7 ppm/° C. Further, in an exemplary embodiment, the core body 34 has an isotropic CLTE. As used herein, an “isotropic CLTE” means that the body reacts to changes in temperatures, i.e., the body expands or contracts, substantially equally in all directions. In one embodiment, the core body 34 is a moldable material. Further, in an exemplary embodiment, the moldable material is a low CLTE liquid crystal polymer. That is, as used herein, a liquid crystal polymer is included in the definition of a “moldable material.” In another embodiment, the core body 34 is a low CLTE ceramic. That is, a ceramic with a

CLTE greater than the defined limit of a “thermally stable CLTE” is not an acceptable ceramic. Further, in an exemplary embodiment, the ceramic core body 34 is made from Steatite L-5™ manufactured by Superior Technical Ceramics Corp., 600 Industrial Park Rd., St. Albans, Vt. 05478. A data sheet disclosing selected characteristics of Steatite L-5™ is attached as Appendix 1.

While specific embodiments of the invention have been described in detail, it will be appreciated by those skilled in the art that various modifications and alternatives to those details could be developed in light of the overall teachings of the disclosure. Accordingly, the particular arrangements disclosed are meant to be illustrative only and not limiting as to the scope of invention which is to be given the full breadth of the claims appended and any and all equivalents thereof.

1. A Rogowski coil comprising:
a thermally stable core including an encircling body);
a winding including a conductive wire; and
said winding disposed in a generally helical coil about said core body.

2. The Rogowski coil of claim 1 wherein:
said core body is a thermally stable core body; and
said core body has a coefficient of linear thermal expansion (CLTE) of less than about one of 15 ppm/° C., 12 ppm/° C., 10 ppm/° C., or 8 ppm/° C.

3. The Rogowski coil of claim 2 wherein said core body has a CLTE of about 7 ppm/° C.

4. The Rogowski coil of claim 2 wherein said core body has an isotropic CLTE.

5. The Rogowski coil of claim 2 wherein said core body is made of a thermally stable CLTE ceramic.

6. The Rogowski coil of claim 5 wherein the ceramic is Steatite L-5.

7. The Rogowski coil of claim 2 wherein said core body is made of moldable material.

8. The Rogowski coil of claim 7 wherein the moldable material is a low CLTE liquid crystal polymer.

9. The Rogowski coil of claim 2 wherein:
said core body has a generally circular cross-sectional shape;
said core body has a cross-sectional diameter of about 0.1 inch;
said core body has an inner toroid diameter of about 0.95 inch; and
said core body has an outer toroid diameter of about 1.05 inches.

10. The Rogowski coil of claim 2 wherein said conductive wire has a CLTE of about 16 ppm/degC.

11. A current sensor assembly comprising:
an output assembly;
a Rogowski coil including a thermally stable core and a winding;
said thermally stable core including an encircling body;
said winding including a conductive wire; and
said winding disposed in a generally helical coil about said core body.

12. The current sensor assembly of claim 11 wherein:
said core body is a thermally stable core body; and
said core body has a CLTE of less than about one of 15 ppm/° C., 12 ppm/° C., 10 ppm/° C., or 8 ppm/° C.

13. The current sensor assembly of claim 12 wherein said core body has a CLTE of about 7 ppm/° C.

14. The current sensor assembly of claim 12 wherein said core body has an isotropic CLTE.

15. The current sensor assembly of claim 12 wherein said core body is made of a low CLTE ceramic.

16. The current sensor assembly of claim 15 wherein the ceramic is Steatite L-5.

17. The current sensor assembly of claim 12 wherein said core body is made of moldable material.

18. The current sensor assembly of claim 17 wherein the moldable material is a low CLTE liquid crystal polymer.

19. The current sensor assembly of claim 12 wherein:
said core body has a generally circular cross-sectional shape;
said core body has a cross-sectional diameter of about 0.1 inch;
said core body has an inner toroid diameter of about 0.95 inch; and
said core body has an outer toroid diameter of about 1.05 inches.

20. The current sensor assembly of claim 12 wherein said conductive wire has a CLTE of about 16 ppm/degC.
